(19) United States
(12) Patent Application Publication
(10) Pub. No.: US 2012/0080777 A1
(43) Pub. Date: Apr. 5, 2012

(54) TRIPLE OXIDATION ON DSB SUBSTRATE

(75) Inventors: Masafumi Hamaguchi, White Plains, NY (US); Ryoji Hasumi, Crompond, NY (US)

(73) Assignee: TOSHIBA AMERICA ELECTRONIC COMPONENTS, INC., Irvine, CA (US)

(21) Appl. No.: 12/895,095

(22) Filed: Sep. 30, 2010

(51) Int. Cl. H01L 29/78; H01L 21/314

(52) U.S. Cl. 257/632; 438/585; 257/E29.255; 257/E21.268

(57) ABSTRACT

According to certain embodiments, a semiconductor structure is formed having a gate oxide formed over a semiconductor substrate. The gate oxide is formed as to have three different regions characterized by a different average thickness of gate oxide in each region. A first oxidation process is performed on a semiconductor substrate having both a Si (110) orientation region and a Si (100) orientation region on a surface thereof. Gate oxide is formed at a faster rate on the Si (110) orientation region of the semiconductor substrate relative to the Si (100) orientation region. A portion of the gate oxide is selectively removed and a second oxidation process is performed to form additional gate oxide. A triple oxide semiconductor substrate is recovered with the gate oxide having three different thickness formed thereon. The triple oxide semiconductor substrate is formed using a decreased number of processing acts.

### TECHNICAL FIELD

Embodiments include semiconductor structures and methods for forming semiconductor structures having a minimum of three different gate oxide thicknesses formed over regions of a semiconductor Direct Silicon Bonded (DSB) substrate.

### BACKGROUND

Modern semiconductor devices are characterized by increasing complexity including the formation of several types of semiconductor devices within an individual integrated circuit. Increased complexity necessitates a greater number of processing acts and increased cost.

In forming field-effect transistor (FET) devices, an insulator is present between a gate electrode and a substrate having a channel formed between source and drain regions formed by doping of a substrate. Different types of FET devices are functionally optimized with different thickness of gate insulator that must be formed on a single wafer substrate during processing. A separate masking and photolithograph act, followed by etching, is employed to fabricated each insulation thickness that is required for each type of FET device to be formed. Further, a substrate having more than one conductivity type on the surface of the substrate is often needed to fabricate the desired integrated circuit, which adds further processing acts and increased costs.

The thickness of the gate insulation, also referred to as the gate oxide, affects several properties of the resulting transistor. As such, FET devices having several different gate thicknesses are increasing required for modern semiconductor devices. For example, various FET devices such as thin gate oxide FET devices, medium thick gate oxide FET devices, and thick gate oxide FET devices all require different gate oxide thickness for optimal performance.

### BRIEF DESCRIPTION OF DRAWINGS

FIG. 1 shows an exemplary process for forming a semiconductor substrate with three thicknesses of gate oxide formed thereon.

FIG. 2 shows an exemplary process for forming a direct silicon bonded substrate.

FIG. 3 shows an exemplary process for forming a semiconductor substrate with three thicknesses of gate oxide formed thereon.

FIG. 4 shows an exemplary silicon bonded substrate with three thicknesses of gate oxide having FET devices formed thereon.

FIG. 5 shows a flow chart methodology for forming a substrate with three thicknesses of gate oxide formed thereon.

### DETAILED DESCRIPTION

According to one embodiment, a semiconductor structure is formed having a gate oxide formed over a semiconductor substrate. The gate oxide is formed as to have three different regions characterized by a different average thickness of gate oxide in each region. A first oxidation process is performed on a semiconductor substrate having both Si (110) and Si (100) orientation regions on a surface thereof. Gate oxide is formed at a faster rate on (110) orientation of Si substrate relative to (100) orientation. A portion of the gate oxide is selectively removed and a second oxidation process is performed to form additional gate oxide. A triple oxide semiconductor substrate is recovered with the gate oxide having three different thickness formed thereon. The triple oxide semiconductor substrate is formed using a decreased number of processing acts.

The semiconductor structure is formed using a direct bond substrate. For example, a substrate having a direct silicon bond (DSB) has a structure in which hybrid-orientation-technology can be used and which does not have a silicon-on-insulator (SOI) structure. The DSB substrate does not have buried oxide (BOX) unlike the SOI substrate. Therefore, ideally, nothing other than silicon is provided on an interface on which silicon layers having different plane orientations (crystal orientations) are bonded together. For example, a Si (110) orientation wafer is bonded on a Si (100) substrate. Direct Silicon Bonded (DSB) is a bulk CMOS hybrid orientation technology that can exploit the higher electron and hole mobility expected from silicon surfaces. The innovations disclosed herein relate to advantageous methods for manufacturing triple oxides gate device on DSB wafer.

SiO₂ is formed on the surface of the wafer with both Si (110) and Si (100) orientation regions. Formation of SiO₂ is a time-dependent oxidation process, wherein the thickness of SiO₂ formed increases in response to process time. The growth of SiO₂ proceeds at a greater rate over the Si (110) regions of the wafer relative to the Si (100) regions. After a fixed period of time, Si (110) region of the wafer has a thickness of SiO₂ and the Si (100) region of the wafer has a second thickness of SiO₂, the first thickness greater than the second thickness. The region of the wafer having SiO₂ of the first thickness formed thereon and a portion of the wafer having SiO₂ of the second thickness is then masked with a resist, the remaining unmasked portion of the wafer is then subjected to etching to remove the SiO₂ formed thereon. A second SiO₂ oxidation process is then performed on the entire DSB wafer. After the second SiO₂ oxidation process, Si (110) region of the wafer has a coating of SiO₂ that is greater than the thickness of any SiO₂ coating formed on Si (100) region of the wafer. Further, Si (100) orientation region of the wafer has at least two sub-regions having different thicknesses of SiO₂ formed thereon. As such, the surface of the DSB wafer has at least three regions of varying thickness of SiO₂ formed thereon.

The methods disclosed herein achieve the formation of DSB substrate having at least three regions with differing thickness of SiO₂ that can be used for a gate oxide. Three different thickness of SiO₂ are achieved through the use of only one resist masking, patterning and etching act performed on DSB substrate after the first SiO₂ formation by taking advantage of different oxidation rate on different silicon orientation. Traditional methods require the performance of at least two resist masking, patterning and etching acts. As such, the method disclosed herein reduce the number of processing acts needed to produce a DSB wafer having at least three different thickness of SiO₂ and allow for more economical production of such wafers.

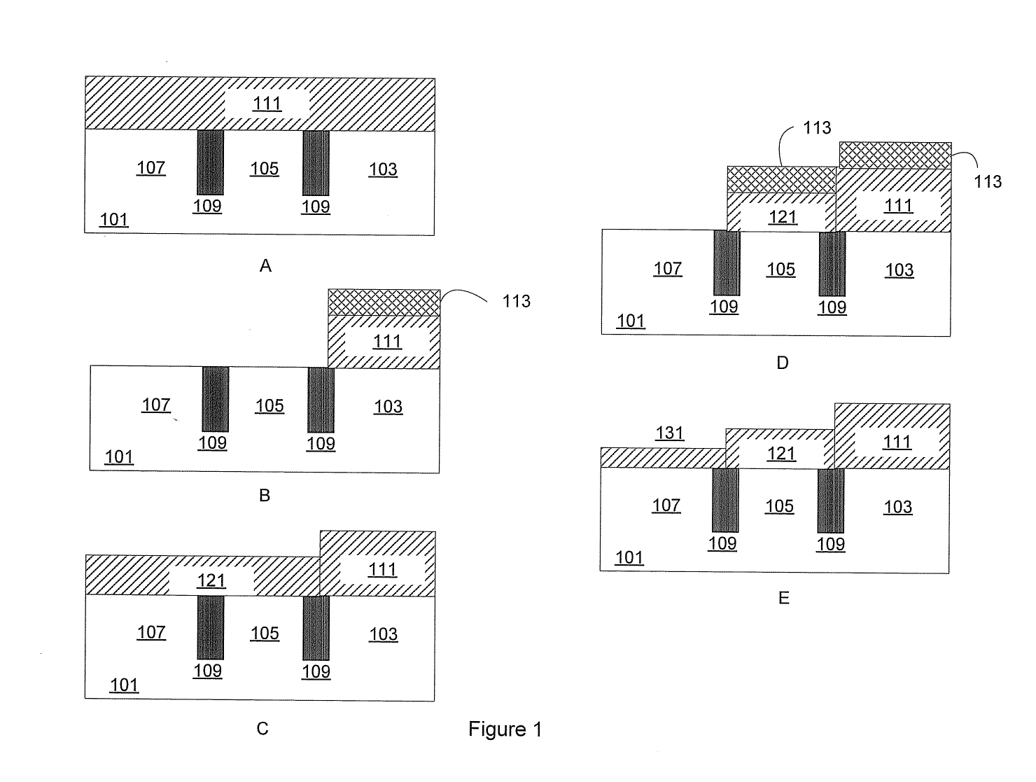

The formation of gate oxide of varying thicknesses on different regions of a wafer can require multiple patterning and removal etching acts using a photoresist or mask. With reference to FIG. 1A, a wafer substrate 101 having at least three regions 103, 105 and 107 separated by shallow trench isolations (STI) 109 is shown. The wafer substrate 101 is subjected to an oxidation process to form a gate oxide 111, typically SiO₂, on the surface of wafer substrate 101. Many oxidation processes are known and typically involve exposure of the wafer substrate to an oxygen-enriched atmosphere and elevated temperature.

With reference to FIG. 1B, a mask or photoresist 113 is applied and patterned to protect a first region of the gate oxide 111, where the unprotected regions of the gate oxide 111 are removed by an etching removal act. For example, the gate oxide 111 formed over the first region 103 is left in place while the oxide from regions 105 and 107 is removed. The wafer 101 is then subjected to a second oxidation process. During the second oxidation process, the gate oxide thickness increases over all areas of the wafer substrate 101, as shown in FIG. 1C. However, the gate oxide 111 formed over region 103 is thicker than the gate oxide 121 formed over regions 105 and 107 due to the prior removal of the oxide initially formed over regions 105 and 107.

In FIG. 1C, a structure is formed having two different gate oxide regions 111 and 121, characterized by varying thickness, formed on substrate wafer 101. In order to form a structure having three different gate oxide thickness, an additional mask patterning and etching removal act is performed. As shown in FIG. 1D, a photoresist or mask 117 is placed and patterned to protect the gate oxide 111 and 121 formed over regions 103 and 105 of the substrate wafer 101. Then, the oxide formed over region 107 is removed using known etching processes. Then, a third oxidation process is performed that increases the gate oxide thickness over all regions of the substrate wafer 101. As shown in FIG. 1E, a substrate wafer 101 having a gate oxide of at least three varying thicknesses, 111, 121 and 131, is formed.

The innovations disclosed herein are now described with reference to the drawings, wherein like reference numerals are used to refer to like elements throughout. In the following description, for purposes of explanation, numerous specific details are set forth in order to provide a thorough understanding of the innovation. It may be evident, however, that the innovation can be practiced without these specific details. In other instances, well-known structures and devices are shown in block diagram form in order to facilitate describing the invention.

Those skilled in the art will recognize that well-known semiconductor fabrication techniques including depositing materials, masking, photolithography, etching, and implanting are useful in forming the described devices or structures. Deposition of materials for forming semiconductor structures can be by low pressure chemical vapor deposition, chemical vapor deposition, atomic layer deposition, and the like. Conserved reference numbers match like elements.

Terms, such as “on,” “above,” “below,” and “over,” used herein, are defined with respect to the plane defined by the surface of a semiconductor substrate. The terms “on,” “above,” “over,” etc. indicate that the subject element is farther away from the plane of the semiconductor substrate than another element referred to as a spatial reference or that the subject element is associated with a referenced element. The term “below” and similar terms indicate that the subject element is closer to the plane of the semiconductor substrate than another element referred to as a spatial reference. The terms “on,” “above,” “below,” and “over,” etc. only indicate a relative spatial relationship and do not necessarily indicate that any particular elements are in physical contact.

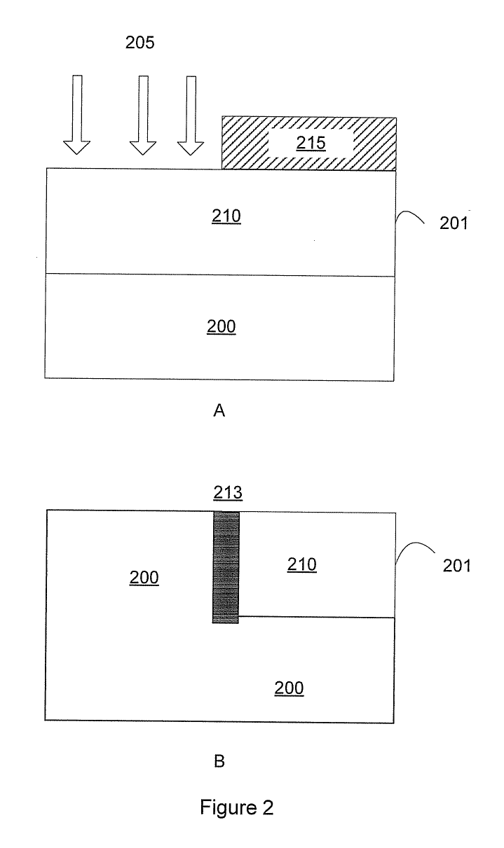

Specific embodiments in accordance with the innovations disclosed herein will be described. FIG. 2 shows the processing of a DSB wafer substrate 201 useful for practicing the innovations described herein. The DSB wafer substrate 201 is formed by the direct bonding of a Si (110) orientation wafer 210 with a Si (100) orientation wafer 200, where semiconductor device structures are to be formed on the surface originating from wafer 210. A portion of wafer 210 is converted to Si (100) orientation by amorphization with known Ge I/II implantation 205, as shown in FIG. 2A. The region of wafer 210 that is to remain as having Si (110) orientation is protected by a patterned mask or photoresist 215 while the remaining unprotected region is amorphized by implantation of Ge I/II 205. As shown in FIG. 2B, the amphorized region of wafer is recrystallized by annealing and converted to be of Si (100) orientation by solid phase epitaxy (SPE). The converted region of the wafer 210 is functionally continuous with the Si (100) orientation of wafer 200. Typically, the junctions between the regions converted into Si (100) orientation and the original Si (110) orientation regions of wafer 210 are sources of defects. As such, an STI 213 is placed between such junctions. Additional STIs 213 can also be placed to assist in the isolation of individual device components fabricated on the wafer.

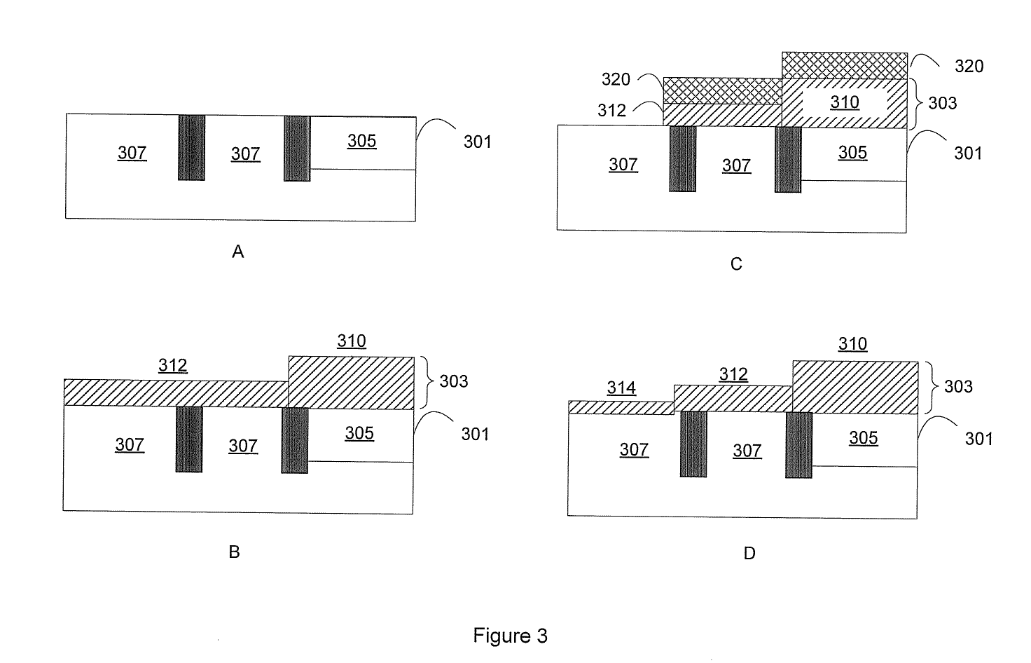

As show in FIG. 3A, a DSB wafer 301 having one or more Si (110) orientation regions 305 and Si (100) orientation regions 307 is recovered for further processing and formation of gate oxides thereon in accordance with innovations disclosed herein. As shown in FIG. 3B, DSB wafer 301 is subjected to a first oxidation process to form a gate oxide thereon. Methods for forming a gate oxide are known. In one embodiment, the gate oxide is SiO₂. The thickness of the gate oxide 303 formed on the wafer 301 is controlled in a time-dependent manner. The rate of gate oxide formation on Si (110) orientation region 305 is faster compared to Si (100) orientation region 307 of the wafer 301. As such, the region of gate oxide 310 formed over the Si (110) orientation region 305 is thicker compared to the region of gate oxide 312 formed over the Si (100) orientation region 307. That is, after the performance of one oxidation process on the wafer 301, two regions of the gate oxide 310 and 312 are formed, where each region of the gate oxide is characterized by a difference in average thickness.

In FIG. 3C, a resist 320 is shown applied over the gate oxide 303. The resist 320 is shown patterned such that a portion of the gate oxide 303 is protected by the resist 320 and a portion of the gate oxide 303 is not protected by the resist 320. Methods of forming and patterning a resist are known, including photolithography techniques. As shown in FIG. 3C, the portion of the gate oxide 303 not protected by the resist 320 is removed. Removal of a portion of the gate oxide 303 can be accomplished with known wet etching and/or dry etching techniques. Those skilled in the art will readily recognize that removal of gate oxide 303 from an area over a Si (110) orientation region of the substrate can be advantageous in certain applications.

In FIG. 3D, the wafer 301 with gate oxide 303 formed thereon is subjected to a second oxidation process. The performance of the second oxidation process increases the thickness of gate oxide 303 over the entire surface of the wafer 301, including addition of gate oxide in region 314 corresponding to where the gate oxide was previously removed. After performance of the second oxidation process, three regions of the gate oxide characterized by a difference in average thickness are formed on the wafer 301. Gate oxide region 310 formed over the Si (110) orientation region 305 of the wafer 301 is the thickest region of the gate oxide 303 due to the higher rate of oxidation of the Si (110) orientation region 305. Gate oxide regions 312 and 314 are formed over the Si (100) orientation region 307 of the wafer 301. Gate oxide region 312 is thicker than gate oxide region 314 due to the removal of gate oxide 303 from the area corresponding to region 314 between the performance of the first and second oxidation processes. The wafer 301 having three different thicknesses of gate oxide formed thereon can be referred to as a triple oxidation direct silicon bonded substrate or a triple oxidation substrate.

In one embodiment, a wafer or substrate has at least three different regions characterized by the average thickness of a gate oxide formed thereon. In one embodiment, a first region has an average thickness of gate oxide at least about 10% greater than a second region and the second region has an average thickness of gate oxide at least about 10% greater than a third region. In another embodiment, a first region has an average thickness of gate oxide at least about 15% greater than a second region and the second region has an average thickness of gate oxide at least about 10% greater than a third region. In yet another embodiment, a first region has an average thickness of gate oxide at least about 15% greater than a second region and the second region has an average thickness of gate oxide at least about 15% greater than a third region. In still yet another embodiment, a first region has an average thickness of gate oxide at least about 20% greater than a second region and the second region has an average thickness of gate oxide at least about 20% greater than a third region.

In one embodiment, a wafer or substrate has at least three different regions characterized by the average thickness of a gate oxide formed thereon, wherein one of the regions has an average thickness of gate oxide at least about 10% greater than the next thickest region. In another embodiment, a wafer or substrate has at least three different regions characterized by the average thickness of a gate oxide formed thereon, wherein one of the regions has an average thickness of gate oxide at least about 15% greater than the next thickest region. In yet another embodiment, a wafer or substrate has at least three different regions characterized by the average thickness of a gate oxide formed thereon, wherein one of the regions has an average thickness of gate oxide at least about 20% greater than the next thickest region. In still yet another embodiment, a wafer or substrate has at least three different regions characterized by the average thickness of a gate oxide formed thereon, wherein one of the regions has an average thickness of gate oxide at least about 25% greater than the next thickest region.

At least three regions of different gate oxide thickness are formed on the substrate or wafer in embodiments disclosed herein. A region of the gate oxide is defined by having a uniform average thickness. In one embodiment, a region of the gate oxide having a uniform average thickness is defined by the region having a relative standard deviation of about 10% or less for gate oxide thickness. In one embodiment, a region of the gate oxide having a uniform average thickness is defined by the region having a relative standard deviation of at most 5% for gate oxide thickness. In one embodiment, a region of the gate oxide having a uniform average thickness is defined by the region having a relative standard deviation of at most 1% for gate oxide thickness. Gate oxide thickness is measured in a direction perpendicular to the plane of the substrate.

In one embodiment, a wafer or substrate has at least three different regions characterized by the average thickness of a gate oxide formed thereon, wherein a first region has an average thickness of gate oxide from about 40 to about 110 Å, a second region has an average thickness of gate oxide from about 60 to about 95 Å, and a third region has an average thickness of gate oxide from about 25 to about 35 Å. In another embodiment, a wafer or substrate has at least three different regions characterized by the average thickness of a gate oxide formed thereon, wherein a first region has an average thickness of gate oxide from about 50 to about 100 Å, a second region has an average thickness of gate oxide from about 70 to about 90 Å, and a third region has an average thickness of gate oxide from about 25 to about 30 Å.

Using the innovations disclosed herein, a wafer or substrate having at least three different thicknesses of a gate oxide formed thereon can be formed with a reduction in the number of process acts required. In accordance with the innovations disclosed herein, only one patterning and removal act is performed on a gate oxide formed over a substrate. A complete patterning and removal act requires at least the following acts: 1) a resist or mask is applied to a gate oxide and the resist or mask is patterned by photolithography or otherwise; and 2) a region of the gate oxide not protected by the patterned resist or mask is removed. The only one patterning and removal act is performed intermediate to a first oxidation processes and a second oxidation processes to generate the gate oxide. An advantageous result of the methods disclosed herein is that a substrate or wafer having at least different thicknesses of a gate oxide formed thereon is recovered after performance of only one patterning and removal act on the gate oxide formed over the substrate or wafer.

A further advantageous feature of the innovations disclosed herein is that a substrate or wafer having at least different thicknesses of a gate oxide formed thereon is recovered after performance of only two oxidation processes to form gate oxide material. Since the rate of gate oxide formation over the wafer or substrate differs between the Si (100) orientation regions and the Si (110) orientation regions of the substrate, three different thickness of gate oxide can be formed by the performance of only two oxidation processes. Three or more oxidation processes, as required by traditional methods, are not required. The first of the two oxidation process is performed prior to a complete patterning and removal act, as described above. The second of the two oxidization presses is performed after a complete patterning and removal act, as described above.

Specifically, the wafer or substrate having at least three different thicknesses of gate oxide is manufactured by the application of only one photoresist or mask to the gate oxide formed on the wafer or substrate. As such, only one photolithography and etching process is performed of the gate oxide to obtain the desired three regions having different gate oxide average thicknesses. After the performance of the second oxidation act, a wafer or substrate having at least three different thicknesses of gate oxide formed thereon is recovered without the application of an additional photoresist after performance of the second oxidation process and without the removal of any of the gate oxide.

The recovered wafer or substrate can be used in downstream processes to fabricate semiconductor devices on the surface of the wafer. Since fewer processing acts are need to fabricate the wafer, an overall cost savings is realized. In particular, field effect transistors can be formed on the recovered triple oxidation substrate using known techniques. Since the triple oxidation substrate shown in FIG. 3D has both Si (100) and Si (110) orientation regions, fabrication of various types of negative channel field effect transistors (nFET) and positive field effect transistors (pFET) can be fabricated on a single wafer.

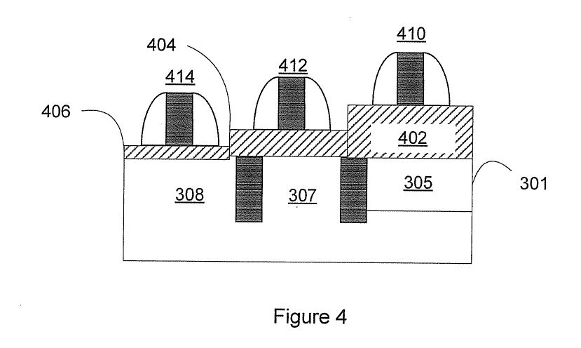

As shown in FIG. 4, different FET devices can be constructed on the triple oxidation substrate. Zero gate FET (ZG-FET) devices 410 can be built on the thickest regions of the gate oxide 402. Extended gate FET (EG-FET) devices 412 can be built on the intermediate thickness regions of the gate oxide 404. Suspended gate (SG-FET) devices 414 can be built on the thinnest thickness regions of the gate oxide 406. Those having skill in the art will recognize that the triple oxidation substrate taught herein can be used in the fabrication of other semiconductor devices, where variance in a gate oxide layer between different types of semiconductor devices fabricated on the triple oxidation wafer is required. In fabricating any FET device or other semiconductor device, the gate oxide is incorporating into the FET device or other semiconductor device as a functional insulation layer.

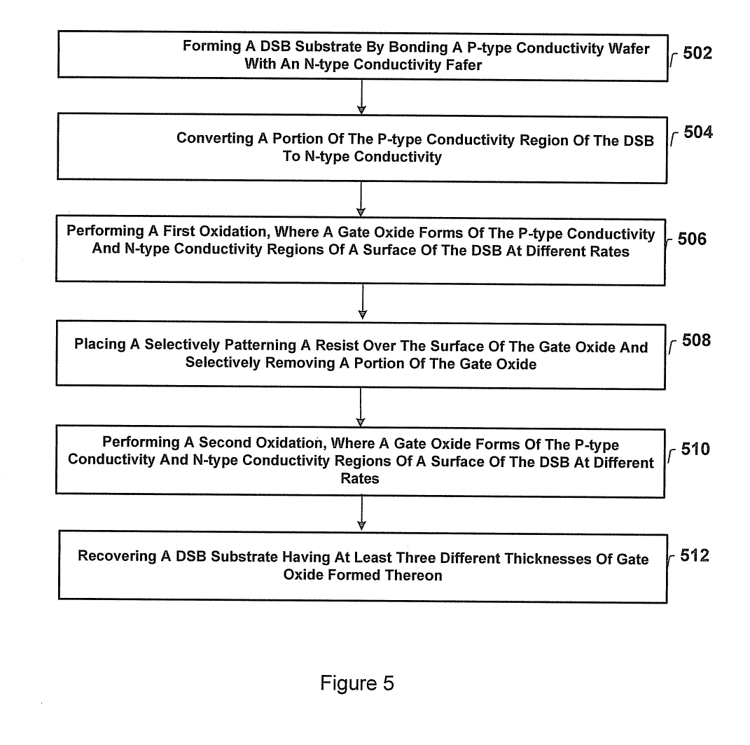

In order to fully describe the innovations disclosed herein, acts for forming a cap layer having high adhesion without the use of plasma will be described in reference to FIG. 5. In act 502, a wafer having Si (110) orientation is bonded to a wafer having Si (100 orientation) to form a DSB substrate. In act 504, a portion of the Si (110) orientation wafer is converted to Si (100) by implantation with Ge I/II followed by recrystallization and solid phase epitaxy. In act 506, a first oxidation process is performed to form a gate oxide on the DSB substrate. A greater thickness of gate oxide is formed over the Si (110) orientation regions of the DSB substrate relative to the Si (100) orientation regions of the DSB substrate. In act 508, a resist or mask is placed over the gate oxide and patterned to protect a portion of the gate oxide and to leave another portion of the gate oxide unprotected. The portion of the gate oxide not protected by the patterned resist is removed. In act 510, a second oxidation process is performed to increase the thickness of gate oxide on the DSB substrate, including the regions of the DSB where gate oxide was removed in act 508. In act 512, a DSB substrate having at least three different regions characterized by the average thickness of a gate oxide formed thereon. The DSB substrate having three different thickness of gate oxide is recovered after the performance of only one act of applying a resist or mask over the gate oxide on the DSB substrate followed by removal of a portion of the gate oxide formed thereon.

With respect to any figure or numerical range for a given characteristic, a figure or a parameter from one range may be combined with another figure or a parameter from a different range for the same characteristic to generate a numerical range.

While certain embodiments have been described, these embodiments have been presented by way of example only, and are not intended to limit the scope of the inventions. Indeed, the novel methods and semiconductor structures described herein can be embodied in a variety of other forms; furthermore, various omissions, substitutions and changes in the form of the methods and systems described herein can be made without departing from the spirit of the inventions. The accompanying claims and their equivalents are intended to cover such forms or modifications as would fall within the scope and spirit of the inventions. With respect to any figure or numerical range for a given characteristic, a figure or a parameter from one range may be combined with another figure or a parameter from a different range for the same characteristic to generate a numerical range.

Other than in the operating examples, or where otherwise indicated, all numbers, values and/or expressions referring to quantities of ingredients, reaction conditions, etc., used in the specification and claims are to be understood as modified in all instances by the term “about.”

While certain embodiments have been described, these embodiments have been presented by way of example only, and are not intended to limit the scope of the inventions. Indeed, the novel methods described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method for fabricating a semiconductor structure having three regions characterized by different thicknesses of a gate oxide, comprising:
providing a direct silicon bonded substrate comprising a Si (100) orientation region and a Si (110) orientation region on the same surface of the direct silicon bonded substrate;
performing a first oxidation process on the direct silicon bonded substrate to form a gate oxide on the surface of the silicon bonded substrate, wherein the gate oxide formed on the Si (110) orientation region of the silicon bonded substrate is thicker than the gate oxide formed on the Si (100) orientation region of the silicon bonded substrate;
removing the gate oxide from a portion of the surface of the direct silicon bonded substrate;
performing a second oxidation process on the direct silicon bonded substrate to form additional gate oxide on the surface of the direct silicon bonded substrate, and
recovering a triple oxidation direct silicon bonded substrate having three different regions of gate oxide formed thereon, each of the three different regions of gate oxide characterized by a different thickness of gate oxide.

2. The method of claim 1, wherein a first region of gate oxide has an average thickness of gate oxide at least about 10% greater than a second region of gate oxide and the second region of gate oxide has an average thickness of gate oxide at least about 10% greater than a third region of gate oxide.

3. The method of claim 1, wherein only one act of removing gate oxide is performed prior to recovering the triple oxidation direct silicon bonded substrate.

4. The method of claim 1, wherein the only oxidization processes performed on the direct silicon bonded substrate prior to recovering the triple oxidation direct silicon bonded substrate are the first oxidation and the second oxidation process.

5. The method of claim 1, wherein removing the gate oxide from a portion of the surface of the direct silicon bonded substrate comprises protecting a portion of the gate oxide produced by the first oxidation process with a mask and removing the portion of the gate oxide not protected by the mask.

6. The method of claim 5, wherein only one act of protecting a portion of the gate oxide formed over the direct silicon bonded substrate with a mask is performed prior to recovering the triple oxidation direct silicon bonded substrate.

7. The method of claim 5, wherein no additional mask is applied to the direct silicon bonded substrate intermediate to the performance of the second oxidation act and the recovery of the triple oxidation direct silicon bonded substrate.

8. The method of claim 1, wherein the first region of gate oxide has an average thickness of gate oxide from about 40 to about 110 Å, the second region of gate oxide has an average thickness of gate oxide from about 60 to about 95 Å, and the third region of gate oxide has an average thickness of gate oxide from about 25 to about 35 Å.

9. The method of claim 1, wherein the direct silicon bonded substrate comprising a Si (100) orientation region and a Si (110) orientation region on the same surface of the direct silicon bonded substrate is formed by the process comprising:
bonding a first wafer having a Si (110) orientation to a second wafer having a Si (100) orientation;
implanting a portion of the surface of the first wafer with one or more selected from Ge(I) and Ge(II); and
converting a portion of the surface of the first wafer to Si (100) orientation, such that the surface of the direct bonded silicon substrate has regions of both a Si (110) orientation region and a Si (100) orientation region.

10. A method for forming a gate oxide on a semiconductor substrate, comprising:
performing a first oxidation process on a semiconductor substrate having both a Si (110) orientation region and a Si (100) orientation region on a surface of the semiconductor substrate to form a gate oxide on the surface of the semiconductor structure, wherein the gate oxide formed over the Si (110) orientation region of the silicon bonded substrate is thicker than the gate oxide formed over the Si (100) orientation region of the silicon bonded substrate;
selectively removing a portion of the gate oxide formed over the semiconductor substrate;
performing a second oxidation process to form additional gate oxide over the semiconductor substrate; and
recovering a triple oxide semiconductor substrate having the gate oxide formed thereon, wherein the gate oxide comprises at least three regions having a different average thickness of gate oxide,
wherein one of the regions of the gate oxide has an average thickness at least about 10% greater than the next thickest region of the gate oxide.

11. The method of claim 10, wherein the first oxidization process and the second oxidation process are the only processes for forming a gate oxide performed on the substrate prior to recovering the triple oxide semiconductor substrate.

12. The method of claim 10, wherein only one act of selectively removing a portion of the gate oxide formed over the semiconductor structure is performed prior to recovering the triple oxide semiconductor substrate.

13. The method of claim 10, wherein a first region of the gate oxide has an average thickness from about 40 to about 110 Å, a second region of the gate oxide has an average thickness from about 60 to about 95 Å, and a third region of the gate oxide has an average thickness from about 25 to about 35 Å.

14. A semiconductor structure, comprising:
a semiconductor substrate having a Si (110) orientation region and a Si (100) orientation region on a surface of the semiconductor substrate;
a gate oxide formed over the surface of the semiconductor substrate; and, the gate oxide comprises at least three regions having a different average thickness of gate oxide, wherein
a first region of the gate oxide has an average thickness at least about 10% greater than a second region of the gate oxide, the second region of the gate oxide has an average thickness at least about 10% greater than a third region of the gate oxide, and
the first region is formed over a region of the semiconductor substrate having Si (110) orientation.

15. The semiconductor structure of claim 14, wherein one or more of the second region and the third region of the gate oxide are formed over a portion of the semiconductor substrate having Si (100) orientation.

16. The semiconductor structure of claim 14, wherein the semiconductor substrate is formed by bonding a first wafer having Si (110) orientation to a second wafer having Si (100) orientation;
implanting a portion of the surface of the first wafer with one or more selected from Ge(I) and Ge(II); and
converting a portion of the surface of the first wafer to Si (100) orientation, such that the surface of the semiconductor substrate wafer has regions of both Si (110) orientation and Si (100) orientation.

17. The semiconductor structure of claim 14, wherein the gate oxide comprises SiO₂.

18. The semiconductor structure of claim 14, wherein the first region of the gate oxide has an average thickness from about 40 to about 110 Å, the second region of the gate oxide has an average thickness from about 60 to about 95 Å, and the third region of the gate oxide has an average from about 25 to about 35 Å.

19. The semiconductor structure of claim 14, the semiconductor structure further comprising one or more field effect transistors formed on the substrate, wherein the gate oxide functions as an insulation layer of the one or more field effect transistors.

20. The semiconductor structure of claim 19, wherein the one or more field effect transistors is selected from the group consisting of suspended gate field effect transistors, extended gate field effect transistors and zero gate field effect transistors.
